(19) United States
(12) Patent Application Publication
(10) Pub. No.: US 2023/0335566 A1
(43) Pub. Date: Oct. 19, 2023

(54) LIGHT SENSOR MANUFACTURING METHOD

(71) Applicants: STMicroelectronics (Crolles 2) SAS, Crolles (FR); COMMISSARIAT A L'ENERGIE ATOMIQUE ET AUX ENERGIES ALTERNATIVES, Paris (FR)

(72) Inventors: Marios BARLAS, Grenoble (FR); Quentin ABADIE, Grenoble (FR)

(73) Assignees: STMicroelectronics (Crolles 2) SAS, Crolles (FR); COMMISSARIAT A L'ENERGIE ATOMIQUE ET AUX ENERGIES ALTERNATIVES, Paris (FR)

(21) Appl. No.: 18/175,360

(22) Filed: Feb. 27, 2023

(30) Foreign Application Priority Data
Apr. 13, 2022 (GR) 20220100322
May 16, 2022 (FR) 2204602

(51) Int. Cl. H01L 27/146

(52) U.S. Cl. CPC H01L 27/1461; H01L 27/14643; H01L 27/1463; H01L 27/14636; H01L 27/14689; G01S 7/4816

(57) ABSTRACT

The present description concerns a manufacturing method comprising, for each photodetector of an array of photodetectors of a light sensor, a use of a mask obtained by directed self-assembly of a block copolymer to form, by a first etch step, at least one first structure on the side of a first surface of the photodetector intended to receive light.

### CROSS-REFERENCE TO RELATED APPLICATION(S)

This application claims the priority benefit of Greek patent application number No 20220100322 filed on Apr. 13, 2022, and of French patent application number No 22/04602, filed on May 16, 2022, entitled “Procédé de fabrication d′un capteur de lumière”, both of which are hereby incorporated by reference to the maximum extent allowable by law.

### BACKGROUND

### Technical Field

The present disclosure generally concerns electronic devices and, more particularly, light sensors, for example time-of-flight sensors.

### Description of the Related Art

Light sensors comprising an array of pixels, where each pixel comprises at least one photodetector arranged in a semiconductor layer, typically a silicon layer, are known. In other words, these known light sensors comprise an array of photodetectors, each arranged in a silicon layer of the sensor.

Among these known light sensors, front-side illuminated sensors and back-side illuminated sensors can be distinguished. In a front-side illuminated sensor, the silicon layer comprising the photodetectors is intended to receive light on its front surface side, that is, on the side of its surface which is coated with a back-end-of-line interconnection structure or BEOL interconnection structure. Conversely, in a back-side illuminated light sensor, the silicon layer comprising the photodetectors is intended to receive light on its rear surface side, that is, on the side of its surface which is opposite to its front surface.

In known light sensors having silicon photodetectors, the quantum efficiency of each pixel of the sensor decreases with the wavelength, following the absorption decrease of silicon with the wavelength. Indeed, the absorption of silicon is strong in the visible portion of the light spectrum, but is low in near infrared, that is, for wavelengths for example in the range from 780 nm to 1,100 μm.

To improve the quantum efficiency of the pixels of these known light sensors intended to operate at near-infrared wavelengths, for example, when the sensor is a direct or indirect time-of-flight sensor, surface structures are provided for each photodetector, on the rear surface side of the silicon layer for a back-side illuminated sensor and on the front surface site for a front-side illuminated sensor. An example of such a surface structure is described in patent application US 2019/0019832 A1.

These known surface structures have, in a plane parallel to the back side of the silicon layer, minimum dimensions, or critical dimensions, in the order of several hundreds of nanometers, for example, greater than or equal to 200 nm. However, the increase of the quantum efficiency of a pixel comprising a photodetector associated with such surface structures with respect to the quantum efficiency of a pixel comprising a similar photodetector but not associated with surface structures decreases with the decrease of the pitch of the pixels, that is, with the decrease of the pitch of the photodetectors or, in other words, with the decrease of the photodetector dimensions.

### BRIEF SUMMARY

The present disclosure is directed to light sensors where the photodetectors are arranged in a silicon layer and are associated with surface structures, for example when these sensors are intended to operate in near infrared and/or are back-side illuminated.

An embodiment provides a manufacturing method comprising, for each photodetector of an array of photodetectors of a light sensor, a use of a mask obtained by directed self-assembly of a block copolymer to form, by a first etch step, at least one first structure on the side of a first surface of the photodetector intended to receive light.

According to an embodiment, the at least one first structure is facing the photodetector.

According to an embodiment, the characteristic length of the block copolymer is shorter than 100 nm, preferably than 50 nm.

According to an embodiment, the directed self-assembly of the block copolymer is implemented by chemo-epitaxy.

According to an embodiment, the directed self-assembly of the block copolymer is implemented by graphoepitaxy.

According to an embodiment, the first etch step comprises a transfer of the mask obtained by directed self-assembly of the block copolymer into a hard mask to form through openings therein, and then an etching from said openings.

According to an embodiment, the directed self-assembly of the block copolymer comprises, for each photodetector, an etching of at least one guide cavity, and a deposition of the block copolymer into said at least one guide cavity.

According to an embodiment, the photodetectors are arranged in a silicon layer and the first structures are formed in an insulating layer resting on the silicon layer.

According to an embodiment, the photodetectors are arranged in a silicon layer and the first structures are formed in the silicon layer.

According to an embodiment, the photodetectors are arranged in a silicon layer and, for each photodetector, said at least one guide cavity is directly etched in the silicon.

According to an embodiment, for at least one of the photodetectors, a plurality of first structures are formed during the first etch step, the pitch of the first structures being preferably smaller than 100 nm.

According to an embodiment, for at least one photodetector, the method further comprises a forming, by a second etch step, of at least one second structure on the side of the first surface, said at least one second structure having, in a plane parallel to said first surface, a smallest dimension greater than a smallest dimension of the first structures.

According to an embodiment, the second etch step is implemented after the first etch step.

According to an embodiment, the self-assembly of the block copolymer is configured so that, for a plurality of said photodetectors, the first structures form a random pattern of fingerprint type.

According to an embodiment, the pitch of the photodetectors is smaller than or equal to 1.5 μm, for example smaller than 1 μm.

According to an embodiment:
the photodetectors are arranged in the silicon layer;
said at least one guide cavity is directly etched in the silicon; and
for at least one photodetector, a width or a diameter of said at least one guide cavity is substantially equal to 1.5 time the characteristic length of the block copolymer.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1A illustrates, in a cross-section view, an embodiment of a step of a light sensor manufacturing method;

FIG. 1B illustrates, in a cross-section view, an embodiment of a step implemented after the step of FIG. 1A;

FIG. 1C illustrates, in a cross-section view, an embodiment of a step implemented after the step of FIG. 1B;

FIG. 1D illustrates, in a cross-section view, an embodiment of a step implemented after the step of FIG. 1C;

FIG. 2A illustrates, in a cross-section view, an alternative embodiment of the step of FIG. 1A;

FIG. 2B illustrates, in a cross-section view, an embodiment of a step implemented after the step of FIG. 2A;

FIG. 2C illustrates, in a cross-section view, an embodiment of a step implemented after the step of FIG. 2B;

FIG. 2D illustrates, in a cross-section view, an embodiment of a step implemented after the step of FIG. 2C;

FIG. 3A illustrates, in a cross-section view, an embodiment of a step implemented after steps similar to the steps of FIGS. 1A to 1D;

FIG. 3B illustrates, in a cross-section view, an embodiment of a step implemented after the step of FIG. 3A;

FIG. 3C illustrates, in a cross-section view, an embodiment of a step implemented after the step of FIG. 3B;

FIG. 4A illustrates, in a cross-section view, another embodiment of a step implemented after steps similar to the steps of FIGS. 1A to 1D;

FIG. 4B illustrates, in a cross-section view, an embodiment of a step implemented after the step of FIG. 4A;

FIG. 5A illustrates, in a cross-section view, still another embodiment of a step implemented after steps similar to the steps of FIGS. 1A to 1D;

FIG. 5B illustrates, in a cross-section view, an embodiment of a step implemented after the step of FIG. 5A;

FIG. 6 illustrates, with curves, the variation of the quantum efficiency gain of photodetectors associated with surface structures as compared with a photodetector which is not associated with surface structures, for different implementations of the surface structures; and

FIG. 7 shows a simplified top view of an array of photodetectors according to an example of implementation.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, known back-side illuminated light sensors, intended to operate in near infrared and comprising silicon photodetectors, have not been described in details, particularly as concerns the implementation of their pixels, the pixel control circuit, the pixel readout circuit, and the circuit for processing the data read from the pixels. However, the embodiments, the implementation modes, and their variants described hereafter are compatible with known light sensors and, in particular, with current implementations of their pixels, of their pixel readout circuits, of their pixel control circuits, and of their pixel data processing circuits. Further, although the present disclosure is made in relation with examples where the sensors are intended to operate in near infrared and to be back-side illuminated, the advantages of the described embodiments apply to front-side illuminated sensors and/or to sensors intended to operate in the visible range.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the rest of the disclosure, unless indicated otherwise, the expression “an element rests on a first layer” means that this element indirectly rests on the first layer, for example, with an interposed intermediate layer between the first layer and the element, or means, preferably, that this element directly rests on the first layer, that is, on top of and in contact with the first layer.

In the following description, the critical dimension of a surface structure corresponds, for example, to the smallest dimension of this structure measured in a plane parallel to the rear surface of the silicon layer comprising the photodetectors.

In the rest of the disclosure, one calls reference pixel a pixel comprising a back-side illuminated silicon photodetector, intended to operate in near infrared, and not associated with surface structures.

The inventors have observed that, as compared with a reference pixel, the increase in the quantum efficiency of a similar pixel, but where the photodetector is associated with surface structures formed on its rear surface side increases with the decrease of the pitch of the structures and/or with the decrease of the critical dimension of the structures, in particular when the structures have critical dimensions for example smaller than 100 nm and a repetition pitch for example smaller than 100 nm.

For structures having a given critical dimension, for example, smaller than 100 nm, and a given repetition pitch, for example, smaller than 100 nm, the more the pitch of the photodetectors decreases, the more the maximum number of structures with which a photodetector can be associated decreases. In other words, for structures having a given critical dimension and a given repetition pitch, in each photodetector, the more the surface area of the photodetectors intended to receive light decreases, the more the maximum number of structures with which a photodetector can be associated decreases.

Usual surface structures have critical dimensions in the order of several hundreds of nanometers, for example critical dimensions greater than or equal to 200 nm, and a repetition pitch also in the order of several hundreds of nanometers, for example a pitch greater than or equal to 200 nm. Thus, for a photodetector pitch smaller than or equal to 1.5 μm, or even smaller than or equal to 1 μm, it becomes impossible to associate a large number of surface structures with the photodetector, for example, a number of surface structures greater than or equal to 5, preferably greater than or equal to 10.

It should be noted that for pixels of relatively large dimensions, for example, pixels having sides with a length greater than 1.5 μm in top view, structures of greater dimensions, for example, of critical dimensions greater than 500 nm, may enable to reach optimum absorption values with a relatively small number of structures, for example smaller than 5. However, the pitch and the critical dimensions of these structures which suit pixels having relatively large dimensions cannot be implemented for pixels having relatively small dimensions, for example, pixels having sides with a length shorter than 1.5 μm, for example, shorter than 1 μm.

It is here provided to overcome all or part of the disadvantages of the previously-described usual light sensor by associating, with each photodetector, at least one surface structure, for example, a plurality of surface structures, preferably at least ten surface structures, obtained by means of a mask itself obtained by directed self-assembly (DSA) of block copolymers. Such a mask may be obtained by implementing the directed self-assembly of the block copolymers by chemo-epitaxy or by graphoepitaxy.

In the present application, one or more surface structures are said to be associated with a photodetector when this or these structures are arranged on the side of the face of the photodetector intended to receive incident light, and are facing (or are directly above) the photodetector. In other words, the structure(s) associated with the photodetector are configured to be traversed by the incident light of the photodetector.

This enables to take advantage from the fact that a mask obtained by directed self-assembly of block copolymers enables to obtain masking structures having small dimensions in a plane parallel to a surface of a layer having these structures resting thereon, for example smaller dimensions than the critical dimensions of known surface structures. For example, when the period, or characteristic length, L0, of the block copolymer is shorter than or equal to 100 nm, for example shorter than or equal to 50 nm, the obtained masking structures each have, in a plane parallel to the silicon layer of the photodetectors, a smallest dimension, or critical dimension, smaller than or equal to 100 nm, or even smaller than or equal to 50 nm. The use of such masking structure enables to form, by etching, surface structures having critical dimensions similar or equal to those of the masking structures, for example surface structures having critical dimensions smaller than or equal to 100 nm, or even smaller than or equal to 50 nm.

Further, this enables to also take advantage of the fact that a mask obtained by directed self-assembly of block copolymers enables to obtain masking structures repeated with a pitch smaller than the repetition pitch of known surfaces structures. For example, when the period, or characteristic length, L0, of the block copolymer is shorter than or equal to 100 nm, for example shorter than or equal to 50 nm, the obtained masking structures each have, in a plane parallel to the silicon layer of the photodetectors, a repetition pitch smaller than or equal to 100 nm, or even smaller than or equal to 50 nm. The use of such masking structure enables to form, by etching, surface structures having a repetition pitch similar or identical to the repetition pitch of the masking structures, for example surface structures having a repetition pitch smaller than or equal to 100 nm, or even smaller than or equal to 50 nm.

As an example, the use of a mask obtained by directed self-assembly of block copolymers enables to form, by etching, surface structures having critical dimensions smaller than 100 nm and a repetition pitch smaller or equal than 100 nm, for example when the characteristic length of the block copolymer used is shorter than 100 nm.

Thus, the use of a mask obtained by directed self-assembly of block copolymers may enable to associate, with each photodetector of a light sensor, a large number of surface structures, for example, at least 5 surface structures, preferably at least 10 surface structures, even when the pitch of the photodetectors becomes smaller than 1.5 μm, for example smaller than 1 μm.

To form surface structures of small dimensions, that is, surface structures having, for example, critical dimensions smaller than 100 nm and having, for example, a repetition pitch smaller than or equal to 100 nm, it could have been devised to use an immersion lithography step to form a mask enabling to form structures by etching. However, immersion photolithography is difficult to implement and cannot always be implemented on the rear surface side of a light sensor due to the topography of the rear surface of the sensor.

Further, it is here also provided, in addition to the surface structures having small critical dimensions formed by means of a mask obtained by directed self-assembly of block copolymers, to optionally form surfaces structures having greater critical dimensions. This enables to associate, for at least certain photodetectors of the sensor, for example, for each photodetector of the sensor, structures having small critical dimensions with structures having large critical dimensions.

As an example, these structures having large dimensions are formed during an etch step, for example, an etch step carried out subsequently to the etch step enabling to form the structures having small dimensions.

As an example, structures having small critical dimensions are surface structures obtained by means of a mask obtained by directed self-assembly of block copolymers, that is, structures having critical dimensions, for example, smaller than or equal to 100 nm, or even 50 nm, and having a repetition pitch, for example, smaller than or equal to 100 nm, or even 50 nm.

As an example, structures having large critical dimensions are surface structures obtained from a conventional photolithography, that is, structures having critical dimensions, for example, greater than or equal to 200 nm and having a repetition pitch, for example, greater than or equal to 200 μm.

As an example, for a given photodetector, structures having small critical dimensions may be stacked to structures having large critical dimensions.

According to another example, for a given photodetector, structures having small critical dimensions may be arranged around structures having large critical dimensions.

Examples of embodiments and of alternative embodiments of a light sensor comprising photodetectors associated with surface structures obtained from a mask itself obtained by directed self-assembly of copolymers will now be described, it being understood that the present disclosure is not limited to these specific method examples.

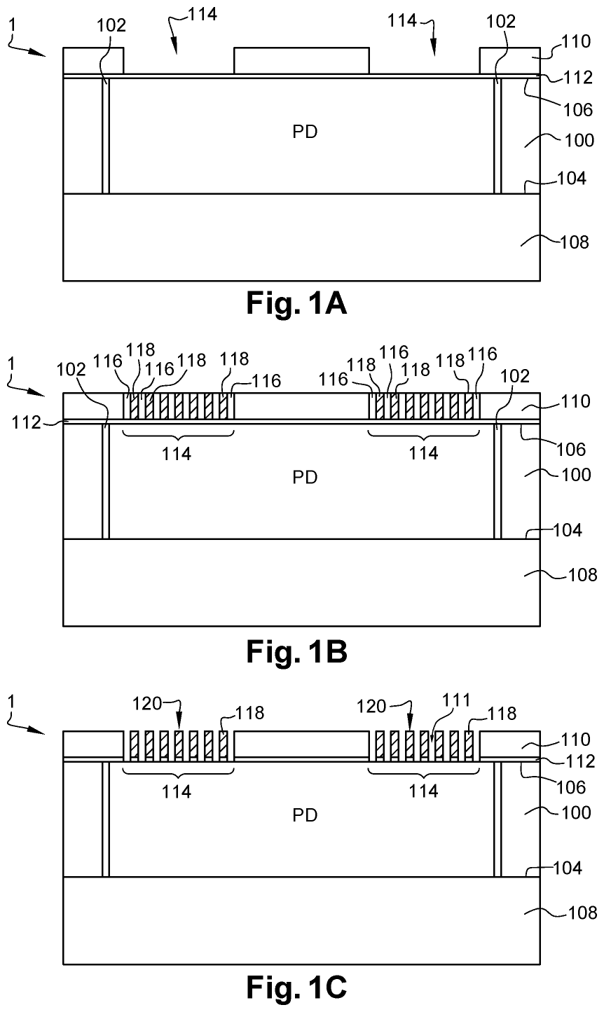

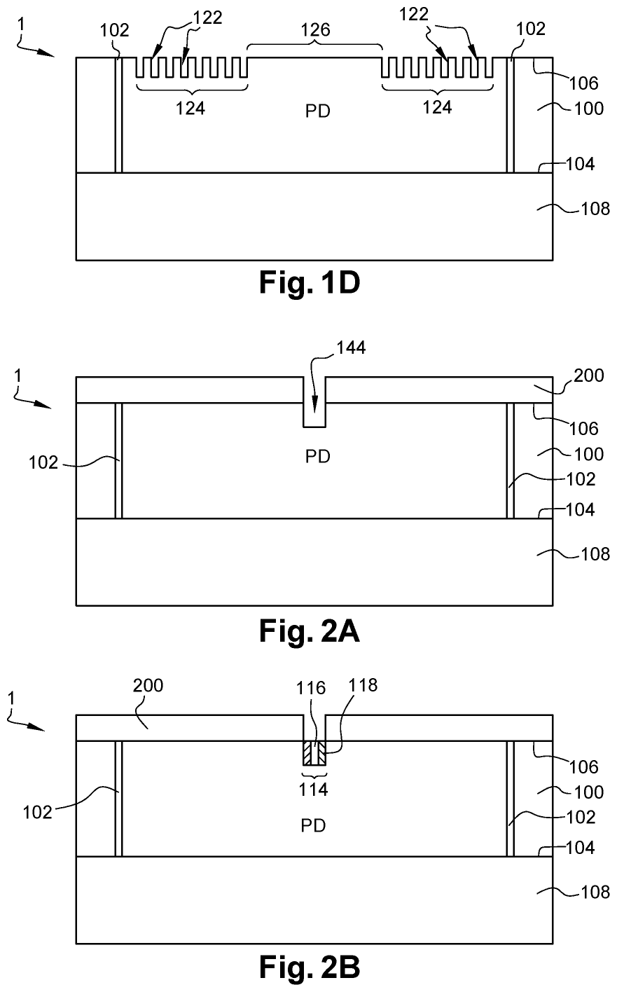

FIGS. 1A to 1D illustrate an example of embodiment of a method of manufacturing a light sensor 1, each figure being a cross-section view illustrating a step of the method.

In this embodiment, the self-assembly of the block copolymer is implemented by graphoepitaxy.

FIG. 1A illustrates, in a cross-section view, a step of this method. FIG. 1A illustrates a portion only of light sensor 1.

Sensor 1 comprises a silicon or semiconductor layer 100. Sensor 1 comprises pixels having photodetectors PD, for example photodiodes or pinned diodes, arranged in silicon layer 100.

In FIG. 1A, and in FIGS. 1B to 1D, a single photodetector PD is shown, although what will be described for the photodetector PD of FIG. 1A may apply to any of the photodetectors PD of sensor 1. For example, each step described for the photodetector PD shown in FIGS. 1A to 1D is implemented simultaneously for each photodetector PD of sensor 1.

Further, although this is not illustrated in FIG. 1A, the photodetectors PD of sensor 1 form an array of photodetectors PD, where the photodetectors are organized in rows and in columns. As an example, the pitch of photodetectors PD is smaller than or equal to 1.5 μm, for example, smaller than or equal to 1 μm.

As an example, the photodetectors PD of sensor 1 are insulated from one another by vertical insulation structures 102, for example, deep trench insulations (DTI) or capacitive deep trench insulations (CDTI).

As an example, each photodetector PD corresponds to a portion of layer 100. As an example, each photodetector PD extends from a front surface 104 of layer 100 to a rear surface 106 of layer 100.

Sensor 1 further comprises a BEOL-type interconnection structure 108.

Interconnection structure 108 rests on the front surface 104 of layer 100. Although this is not detailed in FIG. 1A, interconnection structure 108 comprises, for example, metallization levels embedded in insulating layers which insulate the metallization levels from one another. The metallization levels, in practice portions of conductive layers, are connected to one another by conductive vias crossing insulating layers of structure 108. As an example, interconnection structure 108 electrically couples to one another electronic components (not shown in FIG. 1A) formed on top of and/or inside of layer 100 on the side of its front surface 104, for example, metal oxide semiconductor transistors (MOS) and/or electric contacts (not shown in FIG. 1A) formed on the surface of the interconnection structure 108 opposite to the front surface 104 of layer 100 and enabling to connect sensor 1 to its environment.

At the step of FIG. 1A, a layer 110 has been deposited on layer 100 on the side of its rear surface 106. Layer 110 may be directly deposited on layer 100 or on one or a plurality of layers resting on surface 106 of layer 100. As an example, layer 110 is a resin layer.

In the example of FIG. 1A, layer 110 is deposited on a hard mask layer 112, for example, made of silicon oxide, layer 112 resting on the rear surface 106 of layer 100. In other words, in the example of FIG. 1A, layer 112 is deposited on layer 100 on the side of its rear surface 106, after which layer 110 is deposited on top of and in contact with layer 112.

Still at the step of FIG. 1A, for each photodetector PD, at least one guide cavity 114 is etched in layer 100. More particularly, for each photodetector PD, at least one guide cavity 114 is etched at the surface of photodetector PD. Each guide cavity 114 crosses layer 100 in a direction orthogonal or transverse to surface 106 of layer 100.

As an example, each cavity 114 has, in a plane parallel to surface 106, a smallest dimension, or critical dimension, equal to N*L0, with N a positive integer and L0 the characteristic length of the block copolymer which will be used during the directed self-assembly.

As illustrated in FIG. 1A, in cases where layer 110 rests on top and in contact with an underlying hard mask layer 112, cavities 114 emerge onto this layer 112.

As usual in methods of self-assembly of block copolymers by graphoepitaxy, the dimensions of guide cavities 114 are adapted according to the block copolymer used. The selection of the dimensions of guide cavities 114 according to a block copolymer is within the abilities of those skilled in the art.

FIG. 1B illustrates, in a cross-section view, a next step of the method. More particularly, FIG. 1B shows the structure described in relation with FIG. 1A at a next step of the method.

At the step of FIG. 1B, a block copolymer has been deposited in each cavity 114. Further, an anneal step has been implemented. The anneal step enables the block copolymer to organize, in each cavity, in an alternation of phases 116 comprising first blocks of the block copolymer and of phases 118 comprising second blocks of the block copolymer.

More particularly, the disclosure uses the block copolymer to form an etch mask enabling the forming by etching of surface structures on the side of surface 106 of layer 100, the conditions (temperature, solvent) of the anneal, the mass ratio of the monomers of the first blocks of the block copolymer to the monomers of the second blocks of the block copolymer, and the dimensions of cavities 114 are determined so that each phase 116 and each phase 118 extends along the entire height, or thickness, of the copolymer material arranged in cavities 114, and emerges onto the layer underlying layer 110, that is, here, on layer 112.

FIG. 1C illustrates, in a cross-section view, a next step of the method. More particularly, FIG. 1C shows the structure described in relation with FIG. 1B at a next step of the method.

At the step of FIG. 1C, phases 118 or 116 of the block copolymer have been removed. In this example, phases 116 are removed. Phases 116 are for example removed by a chemical treatment.

As a result, in cavities 114, the phases 118 left in place form masking structures, or, in other words, a mask 120 obtained by directed self-assembly of the block copolymer.

Further, at the step of FIG. 1C, in this example where layer 110 rests on layer 112, the portions of layer 112 exposed after the removal of phases 116 of the block copolymer have been removed by etching. In other words, mask 120 has been transferred into layer 112 to form through openings 111 therein.

FIG. 1D illustrates, in a cross-section view, a next step of the method. More particularly, FIG. 1D shows the structure described in relation with FIG. 1C at a next step of the method.

At the step of FIG. 1D, surface structures 122 have been formed by etching in layer 100, on the side of the rear surface 106 of this layer 100.

More particularly, in this example where layer 110 rests on layer 112, the etching of layer 100 is implemented from the openings formed at the previous step in hard mask 112, after having previously removed mask 120 and layer 110.

As an example, according to the conditions of implementation of the directed self-assembly of the block copolymer, structures 122 may correspond:
to cylindrical holes in layer 100, these holes being each arranged in front of a corresponding recess of mask 120, where a phase 116 has been removed in this example,
to cylindrical pillars in layer 100, these pillars being each arranged in front of a corresponding portion of mask 120, where a phase 118 have been left in place in this example,
to trenches parallel to one another or forming a random pattern of fingerprint type, these trenches being each arranged in front of a corresponding recess of mask 120, where a phase 116 has been removed in this example, or
to blades parallel to one another or forming a random pattern of fingerprint type, each blade being arranged in front of a corresponding portion of mask 120, where a phase 118 has been left in place in this example.

Further, in this example, at the step of FIG. 1D, layer 112 has been removed after the forming of structures 122.

In this example, at the step of FIG. 1D, the portion of layer 100 corresponding to photodetector PD comprises, on the side of its rear surface 106, at least one area 124 provided with structures 122, and at least one area 126 comprising no structure 122. In other words, the photodetector is associated with at least one area 124 provided with structures 122 and with at least one area 126 comprising no structure 122, areas 124 and 126 being formed in front of photodetector PD, on the side of the rear surface 106 of layer 100.

In another example, structures 122 are formed over the entire or almost the entire surface of photodetector PD on the side of the rear surface 106 of layer 100, for example over at least 80% of this surface of photodetector PD. In other words, in another example, only one area 124 provided with structures 122 is formed in front of photodetector PD, on the side of the rear surface 106 of layer 100, and this area 122 extends over the entire or almost the entire surface of the photodetector on the side of the rear surface 106 of layer 100.

At a next step not illustrated, the recesses (trenches or cylindrical holes) formed in layer 100 during the etching to form structures 122 may be each filled with a material having an optical index different from that of layer 100 where structures 122 are formed. As an example, the recesses may be filled with silicon oxide, aluminum oxide, or hafnium oxide. As an example, this material is deposited to entirely fill each recess, and the deposition of the material is for example followed by a step of chemical mechanical polishing (CMP).

The implementation of the method described in relation with FIGS. 1A to 1D comprises the use of the mask 120 obtained by directed self-assembly of the block copolymer to form, during the etching described in relation with the step of FIG. 1D, at least one structure 122 on the side of the rear surface 106 of photodetector PD.

In the example of FIGS. 1A to 1D, the etching to form structures 122 does not directly use mask 120 but rather hard mask 112. However, mask 120 is used to form through openings in hard mask 112, and thus to form structures 122 by etching. In another example not illustrated, hard mask layer 122 is omitted, and the etching to form structures 122 then directly uses mask 120.

In the example of FIGS. 1A to 1D, at the step of FIG. 1C, phases 118 are left in place and phases 116 are removed. The inverse is also possible.

In the example illustrated in FIGS. 1A to 1D, for each photodetector PD, two guide cavities 114 are etched in front of photodetector PD at the step of FIG. 1A. In other examples not illustrated, for each photodetector PD, the number of guide cavities 114 etched in front of photodetector PD may be smaller or greater than two. For example, a single cavity 114 may be etched in front of each photodetector PD. For example, this single cavity 114 extends in front of almost the entire surface of photodetector PD on the side of the rear surface 106 of layer 100, for example, over more than 80% of the surface of photodetector PD, to increase the number of structures 122 formed with respect to the case where such a single hole would cover a smaller portion of the surface of photodetector PD.

In the example of FIGS. 1A to 1D, for each cavity 114, the directed self-assembly of the block copolymer is such that a plurality of structures 122 are formed from the mask 120 corresponding to this cavity. In another example, the directed self-assembly of the block copolymer is such that a single structure 122 is formed from the mask 120 corresponding to a guide cavity.

Although there have been described in relation with FIGS. 1A to 1D examples of embodiment of a method where the directed self-assembly of the block copolymer is implemented by graphoepitaxy, those skilled in the art are capable, based on the above description, of adapting these examples to the case where the directed self-assembly of the block copolymer is implemented by chemo-epitaxy.

For example, those skilled in the art are capable of providing chemical guide structures for the self-assembly by chemo-epitaxy, to obtain, on the side of the rear surface 106 of layer 100, in front of at least one photodetector PD or of each photodetector PD, areas 124 and 126 or a single area 124.

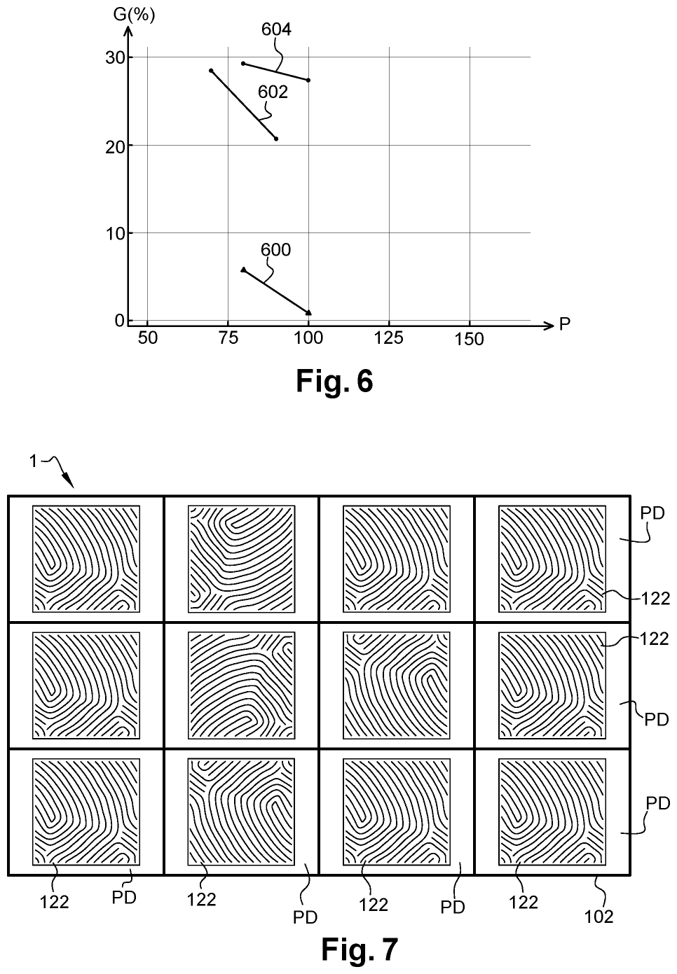

As an example, FIGS. 6 and 7 of patent application EP 3503165 A1 illustrate an example of a chemo-epitaxy method enabling to obtain first areas where the block copolymer is organized in alternated phases perpendicular to the rear surface 106 of layer 100 and second areas where the block copolymer is organized in alternated phases parallel to surface 106. In such an example, the first areas enable to each form an area 124 provided with structures 122, and the second areas enable to each form an area 126 provided with structures 122.

As an example, at least one photodetector PD or each photodetector PD is associated with (or in front of) a plurality of areas 124 and associated with (or in front of) at least one area 126. The dimensions of areas 124 and 126 associated with the photodetector are then, for example, selected so that each area 126 corresponds to a structure having a large critical dimension. In this case, the structures 122 having small critical dimensions are arranged around each structure having a large critical dimension. As another example, the dimensions of the areas 124 and 126 associated with the photodetector are selected so that each area 124 corresponds to a structure having a large critical dimension. In this case, structures 122 having small critical dimensions are arranged inside of each structure having a large critical dimension.

In the embodiment of FIGS. 1A to 1D, guide cavities 114 are formed in layer 110, which rests on the rear surface 106 of layer 100. In an alternative embodiment, guide cavities 114 are formed, that is, etched, directly in layer 100.

It will be within the abilities of those skilled in the art to adapt the different examples described in relation with FIGS. 1A to 1D where the cavities are etched in layer 110 to the case where these cavities are directly etched in layer 100.

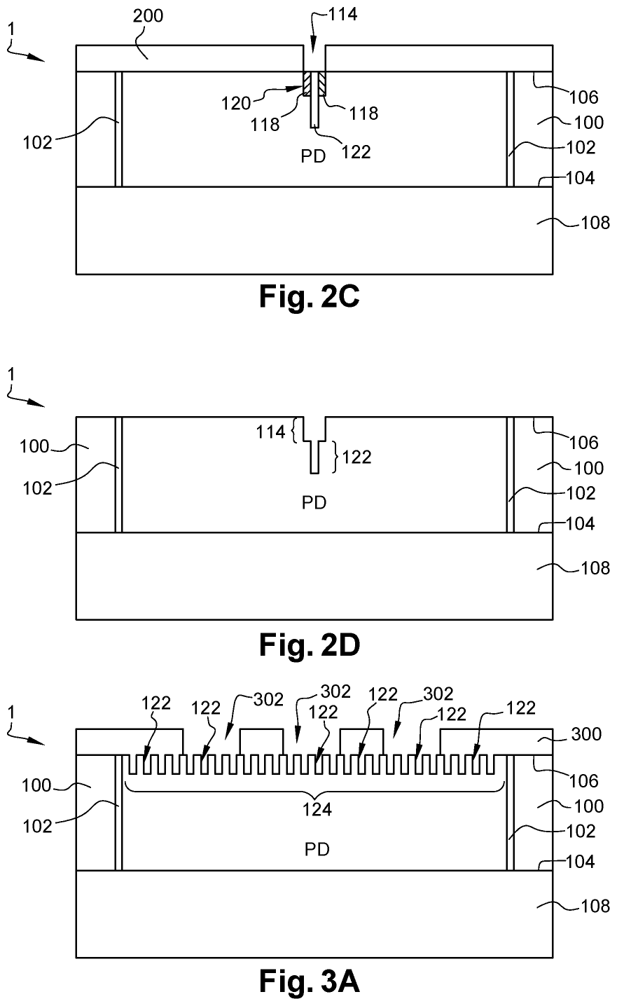

FIGS. 2A to 2D illustrate an example of an alternative embodiment of the method described in relation with FIGS. 1A to 1D, in the case where guide cavities 114 are directly etched in layer 100.

FIGS. 2A to 2D only illustrate a portion of light sensor 1 and, more particularly, a single photodetector PD of sensor 1. However, the steps described in relation with FIGS. 2A to 2D for a single photodetector PD are preferably implemented simultaneously in a plurality of photodetectors PD of sensor 1, for example, in all the photodetectors PD of the sensor.

FIG. 2A illustrates, in a cross-section view, a step of this alternative embodiment of the method of FIGS. 1A to 1D. FIGS. 1A and 2A are similar, and only the differences between these two drawings are here highlighted.

In FIG. 2A, instead of depositing a layer 110 and of forming guide cavities 114 therein as in FIG. 1A, one or a plurality of guide cavities 114 are directly etched in layer 100.

In the example of FIG. 2A, a single cavity 114 is etched for photodetector PD, but in other examples, not illustrated, a plurality of cavities 114 are etched for this photodetector.

As an example, cavity 114 is etched by forming a mask 200, for example, a hard mask, on top of and in contact with the surface 106 of layer 100, mask 200 comprising a through opening at each location where a cavity 114 will be etched.

In this example, the dimensions of cavity 114 are selected so that the mask 120 which will be obtained in cavity 114 by directed self-assembly of the copolymer leads to forming a single structure 122. For example, cavity 114 has a width or a diameter equal to 1.5*L0.

In other examples not illustrated, the dimensions of cavity 114 are selected so that the mask 120 obtained in cavity 114 by directed self-assembly of the copolymer enables to form a plurality of structures 122.

FIG. 2B illustrates, in a cross-section view, a next step of the method. More particularly, FIG. 2B shows the structure described in relation with FIG. 2A at a next step of the method.

At the step of FIG. 2B, the block copolymer has been deposited in each cavity 114. Further, an anneal step has been implemented so that the block copolymer organizes in an alternation of phases 116 and of phases 118. In this example where cavity 114 has a width or a diameter equal to 1.5*L0, a single phase 116 forms, in a central region of cavity 114.

FIG. 2C illustrates, in a cross-section view, a next step of the method. More particularly, FIG. 2C shows the structures described in relation with FIG. 2B at a next step of the method.

At the step of FIG. 2C, the phases 118 or 116 of the block copolymer have been removed. In this example, phase 116 is removed. Phase 116 is for example removed by a chemical treatment. The phases 118 left in place form masking structures or, in other words, a mask 120 obtained by directed self-assembly of the block copolymer.

Further, at the step of FIG. 2C, a portion of layer 100 exposed at the bottom of cavity 114 after the removal of phase 116 of the copolymer has been removed by etching. This results in the forming of a structure 122 here corresponding to a hole or a trench.

In another example not illustrated, phase 118 of the copolymer is removed while phase 116 is left in place and the structure 112 obtained during the etching then corresponds to a pillar or a blade.

FIG. 2D illustrates, in a cross-section view, a next step of the method. More particularly, FIG. 2D shows the structure described in relation with FIG. 2C at a next step of the method.

At the step of FIG. 2D, masks 120 and 200 have been removed. The photodetector PD includes a first end that is closer to the front surface 104 than a second end. The second end is part of the cavity 114 and is coplanar with the rear surface 106. The photodetector has interior sidewalls that are stepped at the transition or interface between cavity 114 and the structure 122. The structure 122 has a first dimension in a first direction that is parallel to the front surface 104. The cavity 114 has a second dimension in the first direction. The first dimension is smaller than the second dimension. The first dimension may be consistent along a second direction that is transverse to the first direction. The second dimension may also be consistent along the second direction.

At a next step, not illustrated, cavity 114 and the portions of layer 100 etched at the step of FIG. 2C, that is, structure 122 in the example of FIGS. 2A to 2D, may be filled with a material having an optical index different from that of silicon, for example, during a step of deposition of the material, which may be followed by a CMP step.

An advantage of etching guide cavities 114 directly into the silicon of layer 100 is that each cavity 114 can then correspond to a structure have greater critical dimension than those of structures 122, for example, to a structure having a large critical dimension. In this case, structures 122 having small dimension are then stacked with structures having greater dimensions.

More generally, structures having greater critical dimensions than those of structures 122, for example, structures having large critical dimensions, may be associated with structures 122.

Other examples of methods enabling to associate structures 122 with structure having greater critical dimensions than those of structures 122, for example, structures having large critical dimensions, will now be described. In these examples, the structures having greater critical dimensions than those of structures 122 are formed during an etch step, for example, an additional etch step implemented after the etching for forming structure 122.

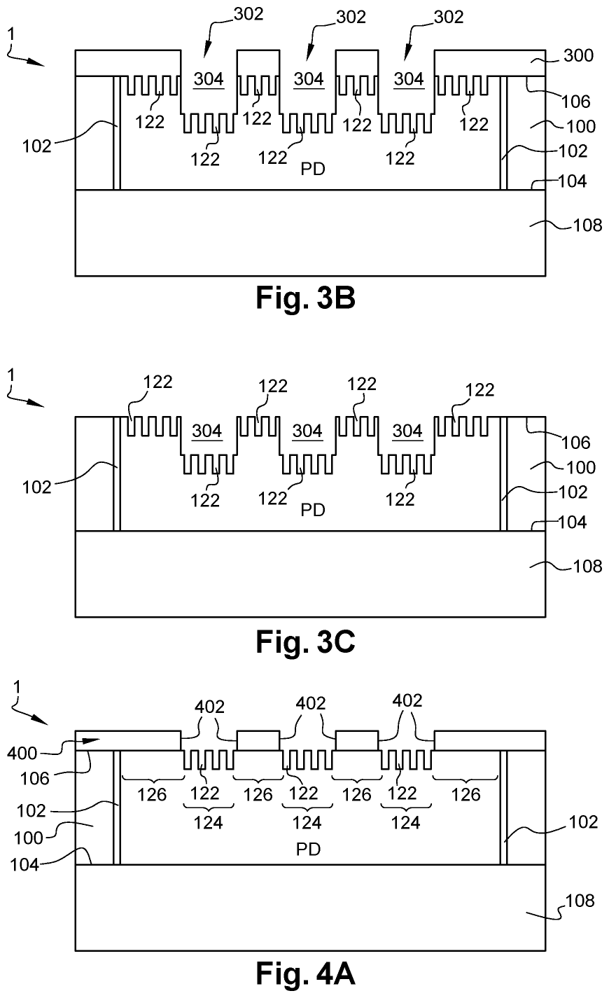

FIGS. 3A to 3C illustrate a first example of a method comprising an additional etch step to form structures having greater critical dimensions than those of structures 122.

FIGS. 3A to 3C illustrate a portion only of light sensor 1 and, more particularly, a single photodetector PD of sensor 1. However, the steps described in relation with FIGS. 3A to 3C for a single photodetector PD are preferably implemented simultaneously in a plurality of photodetectors PD of sensor 1, for example, in all the photodetectors PD of the sensor.

In this first example, as illustrated in FIG. 3A, structures 122 have been formed on the side of the rear surface 106 of layer 100 over almost the entire surface of photodetector PD arranged on the side of surface 106 of layer 100, for example over more than 80% of this surface. Thus, in FIG. 1A, all structures 122 belong to one and the same area 124, and there is no area or space 126 that is associated with photodetector PD (see FIG. 4A).

In this example, structures 122 have been obtained by means of a directed self-assembly implemented by chemo-epitaxy or by graphoepitaxy.

Further, at the step of FIG. 3A, a mask 300 is formed on the side of rear surface 106. Mask 300 comprises portions covering structures 122, and openings 302 emerging onto structures 122. Each opening 302 is arranged at a location where a corresponding structure having greater critical dimension than those of structures 122 is desired to be formed.

In the example of FIG. 3A, mask 300 comprises a plurality of openings 302 for the illustrated photodetector PD. In another example not illustrated, mask 300 may comprise a single opening 302 for photodetector PD.

FIG. 3B illustrates, in a cross-section view, a next step of the method. More particularly, FIG. 3B shows the structure described in relation with FIG. 3A at a next step of the method.

At the step of FIG. 3B, structures 304 having greater critical dimensions than those of structures 122 have been formed in layer 100, by etching on the side of the rear surface 106 of this layer 100. Structures 304 are each formed from a corresponding opening 302.

FIG. 3C illustrates, in a cross-section view, a next step of the method. More particularly, FIG. 3C shows the structure described in relation with FIG. 3B at a next step of the method.

At the step of FIG. 3C, mask 300 has been removed and, at a next step not illustrated, structures 122 and 304 may be filled with a material having an optical index different from that of silicon.

The photodetector PD thus obtained is thus associated with structures 122 having small critical dimensions and with structures 304 having greater critical dimensions, for example with structures 304 having large critical dimensions. Further, certain structures 122 are stacked with a corresponding structure 304, and other structures 122 are not stacked with a structure 304 and are arranged around structure 304.

FIGS. 4A and 4B illustrate a second example of a method comprising an additional etch step to form structures having greater critical dimensions than structures 122.

FIGS. 4A and 4B illustrate a portion only of light sensor 1 and, more particularly, a single photodetector PD of sensor 1. However, the steps described in relation with FIGS. 4A and 4B for a single photodetector PD are preferably implemented simultaneously in a plurality of photodetectors PD of sensor 1, for example, in all the photodetectors PD of the sensor.

In this second example, as illustrated in FIG. 4A, structures 122 have been formed on the side of the rear surface 106 of layer 100. However, conversely to FIG. 3A, on the side of surface 106, there are areas 126 comprising no structure 122, and one or a plurality of areas 124 provided with structures 122.

In this example, structures 122 have been obtained by means of a directed self-assembly implemented by chemo-epitaxy or by graphoepitaxy.

Further, at the step of FIG. 4A, a mask 400 is formed on the side of rear surface 106. Mask 400 comprises portions, each covering a corresponding area 126, and further comprises at least one opening 402 emerging onto structures 122. Each opening 402 emerges onto a corresponding area 124. In the example of FIG. 4A, there are as many openings 402 as areas 124.

FIG. 4B illustrates, in a cross-section view, a next step of the method. More particularly, FIG. 4B shows the structure described in relation with FIG. 4A at a next step of the method.

At the step of FIG. 4B, structures 404 having greater critical dimensions than structures 122 have been formed in layer 100, by etching on the side of the rear surface 106 of this layer 100. Structures 404 are each formed from a corresponding opening 402.

Further, at the step of FIG. 4B, mask 400 has been removed and, at a next step not illustrated, structures 122 and 404 may be filled with a material having an optical index different from that of silicon.

The photodetector PD thus obtained is associated with structures 122 and with at least one structure 404 having greater critical dimension than those of structures 122, for example with at least one structure 404 having a large critical dimension.

Further, in the example of FIGS. 4A and 4B, each structure 122 is stacked with a corresponding structure 404, and no structure 122 is arranged around structures 404. In other words, structures 404 are formed only in front of areas 124 provided with structures 122.

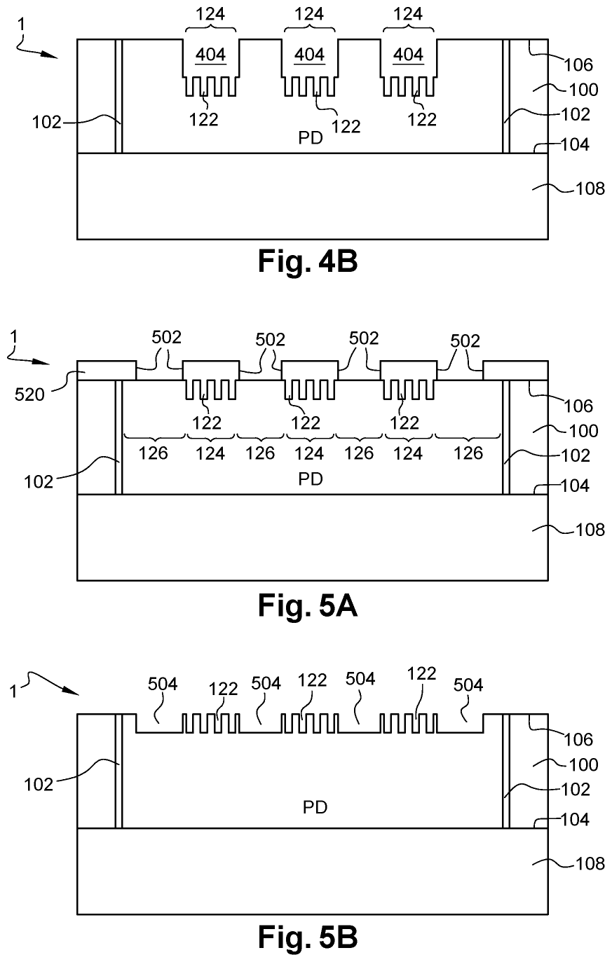

FIGS. 5A and 5B illustrate a third example of a method comprising an additional etch step to form structures having large dimensions.

FIGS. 5A and 5B illustrate a portion only of light sensor 1 and, more particularly, a single photodetector PD of sensor 1. However, the steps described in relation with FIGS. 5A and 5B for a single photodetector PD are preferably implemented simultaneously in a plurality of photodetectors PD of sensor 1, for example, in all the photodetectors PD of the sensor.

In this third example, as illustrated in FIG. 5A, structures 122 have been formed on the side of the rear surface 106 of layer 100. As in FIG. 4A, on the side of surface 106, there are one a plurality of areas 126 comprising no structure 122, and one or a plurality of areas 124 provided with structures 122.

In this example, structures 122 have been obtained by means of a directed self-assembly implemented by chemo-epitaxy or by graphoepitaxy.

Further, at the step of FIG. 5A, a mask 520 is formed on the side of rear surface 106. Mask 520 comprises portions, each covering a corresponding area 124 and thus structures 122. Mask 520 further comprises at least one opening 502 emerging onto an area 126 comprising no structure 122. In this example, mask 520 comprises three openings 502, although in other examples, not illustrated, the mask may comprise one, two, or more than three openings 502.

FIG. 5B illustrates, in a cross-section view, a next step of the method. More particularly, FIG. 5B shows the structure described in relation with FIG. 5A at a next step of the method.

At the step of FIG. 5B, structures 504 having greater critical dimensions than those of structures 122 have been formed in layer 100, by etching on the side of the rear surface 106 of this layer 100. Structures 504 are each formed from a corresponding opening 502.

Further, at the step of FIG. 5B, mask 520 has been removed and, at a next step not illustrated, structures 122 and 504 may be filled with a material having an optical index different from that of silicon.

The photodetector PD thus obtained is associated with structures 122 and with structures 504 having greater critical dimensions than those of structures 122, for example, structures 504 having large critical dimensions.

Further, no structure 122 is stacked with a structure 504, and structures 122 are arranged around structures 504. In other words, structures 504 are only formed in front of areas 126 comprising no structures 122.

Although there has been described in relation with FIGS. 3A to 3C, 4A and 4B, and 5A and 5B the case where structures 3094, 404, and 504 are formed during an etching subsequent to the etching for forming structures 122, in other examples not illustrated, this order of the etchings may be inverted or the two etchings may be implemented simultaneously. The implementation of these other examples is within the abilities of those skilled in the art.

Further, those skilled in the art are capable of adapting the previous examples of a manufacturing method enabling to associate structures 122 with structures having greater critical dimensions than those of structures 122 in the case where the directed self-assembly is implemented by graphoepitaxy and guide cavities 114 are directly etched in layer 100.

There have been described hereabove in relation with FIGS. 1A to 5B examples of embodiments and of variants where the structures are formed in layer 100, by removing by etching portions of this layer 100.

As a variant, structures 122 are formed in an insulating layer resting on the rear surface 106 of layer 100 comprising photodetectors PD. The implementation of such a variant and its adaptation to the various previously-described embodiments is within the abilities of those skilled in the art.

In particular, in such a variant, the etching to form structures 122 comprises removing portions of the insulating layer having structures 122 formed therein rather than portions of layer 100 as previously described. As an example, the insulating layer having structures 122 formed therein has its surface facing surface 106 which is arranged less than 1 μm away from surface 106, for example less than 500 nm away from the surface, or even which is in contact with surface 106.

FIG. 6 illustrates in curves examples of the quantum efficiency gain G of pixels each comprising a photodetector PD associated with structures 122 as compared with a reference pixel (with no structure), for different implementations of the structures and for light received at a wavelength of approximately 940 nm.

In the example of FIG. 6, the structures are cylindrical pillars arranged in an array with a pitch P, the array covering the entire or almost the entire surface of photodetector PD intended to receive light, for example, at least 80% of this surface.

Pitch P, in nanometers, corresponds to the axis of abscissas, the relative gain G, in percents, corresponding to the axis of ordinates.

Curve 600 illustrates the case of pillars 122 having a height equal to 280 nm and a diameter equal to 40 nm, curve 602 illustrating the case of pillars 122 having a height equal to 240 nm and a diameter equal to 50 nm and curve 604 illustrating the case of pillars 122 having a height equal to 240 nm and a diameter equal to 60 nm.

Curves 600, 602, and 604 show that, for pillars 122 of given dimensions, the quantum efficiency gain is larger when the repetition pitch P of pillars 122 decreases.

FIG. 7 shows a simplified top view of an array of photodetectors PD of sensor 1 according to an example of implementation. In the example of FIG. 7, a plurality of photodetectors PD, for example, all the photodetectors PD of sensor 1, are each associated with structures 122 forming a random pattern of fingerprint type. Due to the fact that these patterns are random, they are different from one photodetector PD to the other. As a result, the response of the array of photodetectors PD or, more widely, the response of sensor 1, is unique. This unique response is for example used to identify sensor 1. Said differently, each PD in the sensor 1 is different from each other PD in the sensor.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

In particular, those skilled in the art are capable of selecting a block copolymer according to the shape and to the dimensions targeted for structures 122. An example of a block copolymer is PS-b-PMMA (polystyrene-block-polymethyl methacrylate), and other examples of block copolymers are, for example, given at paragraph [0022] of application EP 3 503 165 A1.

Similarly, to form structures 122, those skilled in the art are capable of selecting a given graphoepitaxy method from among known graphoepitaxy methods. For example, although this has not been previously described, those skilled in the art are capable of providing to functionalize the bottom and/or the walls of the guide cavities according to the selected copolymer, to obtain the mask which will be used for the forming of structures 122 by etching. An example of such a functionalization is described in patent application EP 3 465 739 A1.

Further, to form structures 122, those skilled in the art are capable of selecting a given chemo-epitaxy method from among known chemo-epitaxy methods. For example, although this has not been previously detailed, those skilled in the art are capable of selecting the chemo-epitaxy method from among the LiNe method, the COOL method, the SMART method, or also the method described in patent application EP 3 503 165 A1.

The obtaining of structures having critical dimensions smaller than 200 nm, for example, smaller than 100 nm, or even than 50 nm, with a repetition pitch smaller than 200 nm, for example smaller than 100 nm, or even than 50 nm, enables to improve the quantum absorption in near infrared of a back-side illuminated pixel having a silicon photodetector with sides (in top view) having a length shorter than 1.5 μm, or even than 1 μm. However, structures having these critical dimensions and this repetition pitch may also enable to improve the quantum absorption in near infrared of a front-side illuminated pixel having a silicon photodetector with sides (in top view) having a length shorter than 1.5 μm, or even than 1 μm, or to improve the quantum absorption in the visible range of a pixel having a front-side or back-side illuminated silicon photodetector. Thus, the present disclosure is not limited to pixels which are intended to operate in near infrared and/or which have silicon photodetectors having sides with a length shorter than 1.5 μm and/or which are back-side illuminated.

Manufacturing method may be summarized as including for each photodetector (PD) of an array of photodetectors of a light sensor (1), a use of a mask (120) obtained by directed self-assembly of a block copolymer to form, by a first etch step, at least one first structure (122) on the side of a first surface (106) of the photodetector intended to receive light.

The characteristic length of the block copolymer may be shorter than 100 nm, preferably than 50 nm.

The directed self-assembly of the block copolymer may be implemented by chemo-epitaxy.

The directed self-assembly of the block copolymer may be implemented by graphoepitaxy.

The first etch step may include a transfer of the mask (120) obtained by directed self-assembly of the block copolymer into a hard mask (112) to form through openings therein, and then an etching from said openings.

The directed self-assembly of the block copolymer may include, for each photodetector (PD), an etching of at least one guide cavity (114), and a deposition of the block copolymer into said at least one guide cavity (114).

The photodetectors (PD) may be arranged in a silicon layer (100) and the first structures (122) may be formed in an insulating layer resting on the silicon layer (100).

The photodetectors (PD) may be arranged in a silicon layer (100) and the first structures (122) may be formed in the silicon layer (100).

The photodetectors (PD) may be arranged in a silicon layer (100) and, for each photodetector (PD), said at least one guide cavity (114) is directly etched in the silicon (100).

For at least one of the photodetectors (PD), a plurality of first structures (122) may be formed during the first etch step, the pitch of the first structures (122) being, preferably, smaller than 100 nm.

For at least one photodetector (PD), the method may further include a forming, by a second etch step, of at least one second structure (304, 404, 504) on the side of the first surface (106), said at least one second structure (304, 404, 504) having, in a plane parallel to said first surface (106), a smallest dimension greater than a smallest dimension of the first structures (122).

The second etch step may be implemented after the first etch step.

The self-assembly of the block copolymer may be configured so that, for a plurality of said photodetectors (PD), the first structures (122) form a random pattern of fingerprint type.

The pitch of the photodetectors (PD) may be smaller than or equal to 1.5 μm, for example, smaller than 1 μm.

The photodetectors (PD) may be arranged in the silicon layer (100); said at least one guide cavity (114) may be directly etched in the silicon (100); and for at least one photodetector (PD), a width or a diameter of said at least one guide cavity (114) may be substantially equal to 1.5 time the characteristic length of the block copolymer.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming, by a first etch step, at least one first structure on a first surface of a photodetector of an array of photodetectors of a light sensor, the forming including using a mask that is a directed self-assembly of a block copolymer.

2. The method according to claim 1, wherein the at least one first structure is facing the photodetector.

3. The method according to claim 1, wherein a length of the block copolymer is less than 100 nm.

4. The method according to claim 3, wherein a length of the block copolymer is less than 50 nm.

5. The method according to claim 1, wherein using the directed self-assembly of the block copolymer includes implementing by chemo-epitaxy.

6. The method according to claim 1, wherein using the directed self-assembly of the block copolymer includes implementing by graphoepitaxy.

7. The method according to claim 6, wherein the first etch step comprises forming through openings and then etching from the openings by transferring the mask by directed self-assembly of the block copolymer into a hard mask.

8. The method according to claim 6, wherein the directed self-assembly of the block copolymer comprises, for each photodetector, etching of at least one guide cavity, and a depositing the block copolymer into the at least one guide cavity.

9. The method according to claim 1, wherein the photodetectors are in a silicon layer and the first structures are in an insulating layer on the silicon layer.

10. The method according to claim 8, wherein the photodetectors are in a silicon layer and, for each photodetector, etching the at least one guide cavity directly in the silicon.

11. A method, comprising:
forming a first layer on a first surface of a semiconductor layer;
forming a second layer on the first layer;
forming a block copolymer including a plurality of first phases and a plurality of second phases;
removing the plurality of first phases;
forming a plurality of first openings in the semiconductor layer through spaces between the plurality of second phases.

12. The method of claim 11, wherein the first opening has a first dimension in a first direction, the first dimension corresponds to the spaces between the plurality of second phases.

13. The method of claim 11, wherein forming the plurality of first openings includes performing a first etch step, a pitch of the first openings being, smaller than 100 nm.

14. The method according to claim 13, comprises a forming, by a second etch step, a plurality of second openings, the at least one second opening having, in a first direction substantially parallel to the first surface, a first smallest dimension that is greater than a second smallest dimension of the first openings.

15. The method according to claim 11, wherein the first openings are in random pattern of fingerprint type.

16. A device, comprising:
a substrate having a first surface;
an interconnection structure on a second surface of the substrate;
a plurality of insulation structures that extend from the first surface to the second surface;
a plurality of photodetectors in a first surface of the substrate, each photodetector being spaced from an adjacent photodetector by ones of the plurality of insulation structures, each photodetector having a unique pattern of first structures, each first structure including an opening in the first surface of the substrate.

17. The device of claim 16, wherein each first structure includes a second structure formed within the first structure, the first structure having a first dimension in a first direction and the second structure has a second dimension in the first direction, the second dimension being less than the first dimension.
